(19) United States
(12) Patent Application Publication
(10) Pub. No.: US 2011/0036288 A1
(43) Pub. Date: Feb. 17, 2011

(54) SR-TI-O-BASED FILM FORMING METHOD AND STORAGE MEDIUM

(75) Inventors: Yumiko Kawano, Yamanashi (JP); Susumu Arima, Yamanashi (JP); Akinobu Kakimoto, Yamanashi (JP); Toshiyuki Hirota, Tokyo (JP); Takakazu Kiyomura, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignees: TOKYO ELECTRON LIMITED, Tokyo (JP); ELPIDA MEMORY, INC., Tokyo (JP)

(21) Appl. No.: 12/918,165

(22) PCT Filed: Feb. 18, 2009
(86) PCT No.: PCT/JP2009/052728

§ 371 Date: Nov. 5, 2010

(30) Foreign Application Priority Data
Feb. 19, 2008 (JP) 2008-037564

(51) Int. Cl. C30B 1/02

(52) U.S. Cl. 117/8

(57) ABSTRACT

Disclosed is a method for Sr—Ti—O-base film formation. The method comprises placing a substrate with a Ru film formed thereon in a treatment vessel, introducing a gaseous Ti material, a gaseous Sr material, and a gaseous oxidizing agent into the treatment vessel to form a first Sr—Ti—O-base film having a thickness of not more than 10 nm on the Ru film, annealing the first Sr—Ti—O-base film for crystallization, introducing a gaseous Ti material, a gaseous Sr material, and a gaseous oxidizing agent into the treatment vessel to form a second Sr—Ti—O-base film on the first Sr—Ti—O-base film, and annealing the second Sr—Ti—O-base film for crystallization.

### FIELD OF THE INVENTION

The present invention relates to an Sr—Ti—O film forming method for forming an Sr—Ti—O-based film such as an SrTiO₃ film or the like and a storage medium.

### BACKGROUND OF THE INVENTION

Along with the trend toward high integration of integrated circuits in semiconductor devices, DRAMs is required to have a smaller area of memory cells and a larger memory capacity. To this end, metal-insulator-metal (MIM) capacitors have attracted attention. MIM-structured capacitors employ a high-k dielectric material such as strontium titanate (SrTiO₃) as a material of an insulating film (dielectric film).

A physical vapor deposition (PVD) method has been conventionally used as a method for forming an SrTiO₃ film for DRAM capacitors. However, because of its poor step coverage, an atomic layer deposition (ALD) method is recently and widely used as a method for forming a film by using an organic Sr source material and an organic Ti source material as an organic metal compound source material and O₃ gas as an oxidizer (see, e.g., “Plasma enhanced atomic layer deposition of SrTiO₃ thin films with Sr(tmhd)₂ and Ti(i-OPr)₄”, J. H. Lee et al., J. Vac. Scl. Technol. A20(5), September/October 2002).

However, an SrTiO₃ film formed by the ALD method is not easily crystallized by annealing compared to that formed by the PVD method. Further, a film formed by the ALD method is not easily crystallized even though the film is exposed to the same thermal load (temperature x time) as that by which a film formed by the PVD method is crystallized. Since the Sr—Ti—O-based material has a low dielectric constant in an amorphous state, it needs to be crystallized.

### SUMMARY OF THE INVENTION

It is therefore an object of the present invention to provide an Sr—Ti—O-based film forming method capable of forming an Sr—Ti—O-based film having a high dielectric constant by stably crystallizing SrTiO₃ crystals.

It is another object of the present invention to provide a storage medium which stores a program for executing a method for achieving the above-described purpose.

In accordance with the present invention, there is provided an Sr—Ti—O-based film forming method including: loading a substrate having an Ru film formed thereon into a processing chamber; forming a first Sr—Ti—O-based film having a thickness smaller than or equal to about 10 nm on the Ru film by introducing a gaseous Ti source material, a gaseous Sr source material and a gaseous oxidizer into the processing chamber; and annealing the first Sr—Ti—O-based film to crystallize. The Sr—Ti—O-based film forming method includes: forming a second Sr—Ti—O-based film on the first Sr—Ti—O-based film by introducing the gaseous Ti source material, the gaseous Sr source material and the gaseous oxidizer into the processing chamber; and annealing the second Sr—Ti—O-based film to crystallize.

The Sr—Ti—O-based film forming method may further include forming a third Sr—Ti—O-based film which is substantially uncrystallized after annealing the second Sr—Ti—O-based film. Herein, the third Sr—Ti—O-based film may be formed under a condition in which an Sr/Ti atomic ratio is smaller than 1.

Further, the Sr—Ti—O-based film forming method may further include forming an oxide film which is substantially uncrystallized after annealing the second Sr—Ti—O-based film. The oxide film may be one of a TiO₂ film, an Al₂O₃ film and an L₂O₃ film.

It is preferred that the annealing of the first Sr—Ti—O-based film and the annealing of the second Sr—Ti—O-based film are performed under a non-oxidizing atmosphere at a temperature within a range from about 500 to 750° C.

Further, after annealing the second Sr—Ti—O-based film to crystallize, a cure process may be performed under an oxidizing atmosphere so that oxygen is introduced into the film. The curing is preferably performed at a temperature within a range from about 350 to 500° C., more preferably from about 400 to 450° C.

Furthermore, the forming of the first Sr—Ti—O-based film and/or the second Sr—Ti—O-based film may be executed by performing each of an SrO film formation phase and an TiO film formation phase multiple times, wherein the SrO film formation phase includes: introducing the gaseous Sr source material into the processing chamber and adsorbing the Sr source material onto the substrate; oxidizing the Sr source material by introducing the gaseous oxidizer into the processing chamber; and purging the processing chamber, and the TiO film formation phase includes: introducing the gaseous Ti source material into the processing chamber and adsorbing the Ti source material onto the substrate; oxidizing the Ti source material by introducing the gaseous oxidizer into the processing chamber; and purging the processing chamber. In that case, it is preferred that a sequence including performing the SrO film formation phase multiple times successively and/or performing the TiO film formation phase multiple times successively is repeated.

Herein, the Sr source material is preferably a cyclopentadienyl compound. Preferably, the Ti source material is alkoxide and the oxidizer is O₃ or O₂.

Preferably, the formation of the first Sr—Ti—O-based film and the formation of the second Sr—Ti—O-based film are carried out under a condition in which an Sr/Ti atomic ratio in the film ranges from about 0.9 to 1.4.

In accordance with another aspect of the present invention, there is provided a storage medium for storing a program which runs on a computer and, when executed, controls a film forming apparatus to perform a method for Sr—Ti—O-based film formation. The method includes: loading a substrate having an Ru film formed thereon into a processing chamber; forming a first Sr—Ti—O-based film having a thickness smaller than or equal to about 10 nm on the Ru film by introducing a gaseous Ti source material, a gaseous Sr source material and a gaseous oxidizer into the processing chamber; annealing the first Sr—Ti—O-based film to crystallize; forming a second Sr—Ti—O-based film on the first Sr—Ti—O-based film by introducing the gaseous Ti source material, the gaseous Sr source material and the gaseous oxidizer into the processing chamber; and annealing the second Sr—Ti—O-based film to crystallize.

In accordance with the present invention, the first Sr—Ti—O-based film having a thickness smaller than or equal to about 10 nm is formed on the base Ru film which is used in the lower electrode or the like, by introducing the gaseous Ti source material, the gaseous Sr source material and the gaseous oxidizer into the processing chamber, and annealed for crystallization. Next, the second Sr—Ti—O-based film is formed and annealed for crystallization in the same manner. As a result, a high dielectric constant can be achieved.

The present inventors have conceived the present invention by discovering that, although it is generally difficult to crystallize a thin Sr—Ti—O-based film, an Sr—Ti—O-based film formed on a base Ru film by an ALD method can be easily crystallized even if its thickness is smaller than or equal to about 10 nm, and also that the second Sr—Ti—O-based film formed on the first Sr—Ti—O-based film that has been annealed for crystallization can be more easily crystallized compared to the first Sr—Ti—O-based film formed directly on the Ru film. Further, the present inventors have discovered that crystals of the first Sr—Ti—O-based film and the second Sr—Ti—O-based film are connected in a film thickness direction and this leads to stable formation of large SrTiO₃ single crystal grains crystallized in the film thickness direction which ensures a high dielectric constant.

Meanwhile, when the SrTiO₃ is crystallized in single crystal grains in the film thickness direction, a leakage current may increase. However, the occurrence of the leakage current can be prevented by blocking grain boundaries by forming film a third Sr—Ti—O-based film that is not easily crystallized or by forming an oxide film such as a TiO₂ film, an Al₂O₃ film, an La₂O₃ film or the like that is substantially not crystallized, on the annealed second Sr—Ti—O-based.

### BRIEF DESCRIPTION OF THE DRAWINGS

FIG. 1 is a cross sectional view showing a schematic configuration of a film forming apparatus which can be used to perform a film forming method of the present invention;

FIGS. 2A to 2F provide process cross sectional views for explaining a film forming method of the present invention;

FIG. 3 illustrates a scanning electron microscopic image showing an Sr—Ti—O film formed by the film forming method of the present invention;

FIG. 4 describes a film forming sequence of the film forming method of the present invention;

FIG. 5 presents relation between an Sr/Ti atomic ratio in an Sr—Ti—O-based film and a (110) peak height of an SrTiO₃ crystal which is measured by an XRD after annealing; and

FIG. 6 depicts another example of a processing gas supply mechanism.

### DETAILED DESCRIPTION OF THE EMBODIMENT

Hereinafter, the embodiments of the present invention will be described with reference to the accompanying drawings.

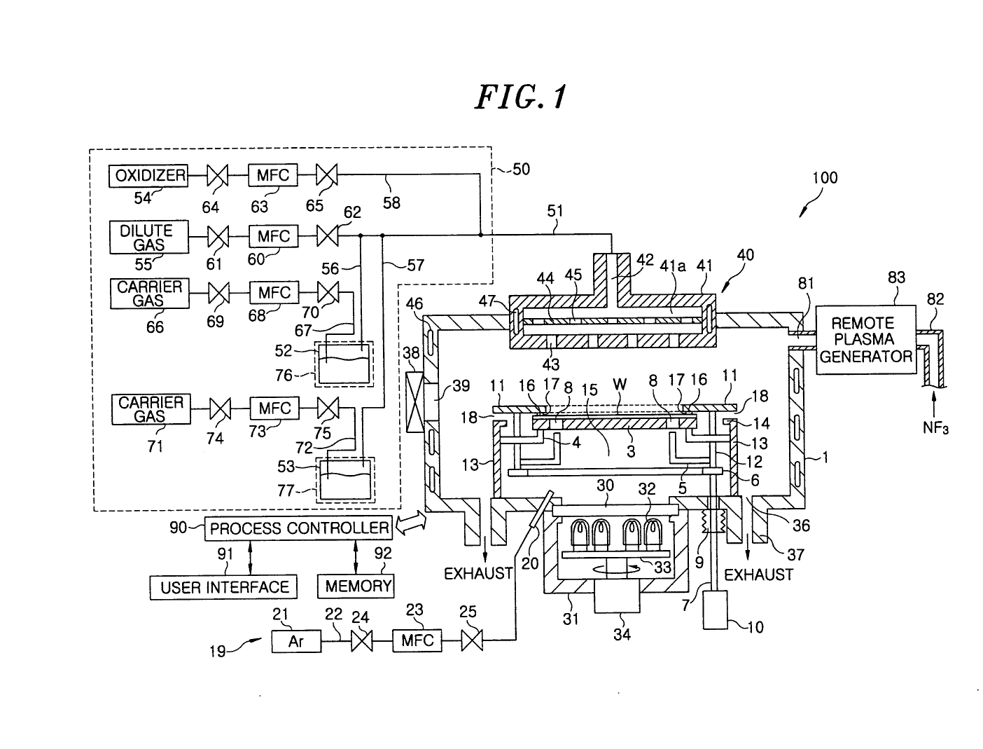

FIG. 1 is a cross sectional view showing a schematic configuration of a film forming apparatus which can be used to perform a film forming method of the present invention. A film forming apparatus 100 shown in FIG. 1 includes a cylindrical or box-shaped processing chamber 1 made of, e.g., aluminum or the like, in which there is provided a mounting table 3 for mounting thereon a semiconductor wafer W serving as a substrate to be processed. The mounting table 3 is made of, e.g., a carbon material, aluminum compound such as aluminum nitride, or the like, having a thickness of about 1 mm.

A cylindrical partition wall 13 made of, e.g., aluminum, stands on a bottom portion of the processing chamber 1 at an outer peripheral side of the mounting table 3. A bent portion 14 is formed by horizontally bending an upper portion of the partition wall 13 in an L shape. By installing the cylindrical partition wall 13, an inert gas purge area 15 is formed at a backside of the mounting table 3. A top surface of the bent portion 14 is positioned substantially on a same plane with a top surface of the mounting table 3 and is spaced from the outer periphery of the mounting table 3 with connection rods 12 inserted therebetween. The mounting table 3 is supported by three supporting arms 4 (only two being shown) extending from an upper inner wall of the partition wall 13.

A plurality of, e.g., three, lifter pins 5 (only two being shown) are provided under the mounting table 3 so as to protrude upward from a ring-shaped support member 6 in an L shape. The support member 6 is provided to be raised and lowered by an elevation rod 7 which passes through the bottom portion of the processing chamber 1, and the elevation rod 7 is raised and lowered by an actuator 10 positioned below the processing chamber 1.

The mounting table 3 has insertion through holes 8 at portions corresponding to the lifter pins 5, so that the lifter pins 5 can pass through the insertion through holes 8. Thus, the lifter pins 5 can be raised by the actuator 10 through the elevation rod 7 and support member 6, and lift up the semiconductor wafer W. The portion of the processing chamber 1 into which the elevation rod 7 is inserted is covered with a bellows 9 to prevent air from entering the processing chamber 1 through this portion.

A clamp ring member 11 made of ceramic, e.g., aluminum nitride, and having a substantially annular shape conforming to a contour shape of the circular semiconductor wafer W is arranged above a peripheral portion of the mounting table 3 so as to hold and fix the peripheral portion of the semiconductor wafer W onto the mounting table 3. The clamp ring member 11 is connected to the support member 6 via the connection rods 12, and thus can be moved up and down together with the lifter pins 5. The lifter pins 5, the connection rods 12 or the like are made of ceramic such as alumina or the like.

A plurality of contact protrusions 16 are formed below a lower surface of an inner peripheral side of the clamp ring member 11 while being spaced from each other at a substantially regular interval in a circumferential direction. When the semiconductor wafer W is clamped, bottom surfaces of the contact protrusions 16 come into contact with the top surface of the peripheral portion of the semiconductor wafer W and press the wafer W.

Further, each of the contact protrusions 16 has a diameter of about 1 mm and a height of about 50 μm, so that a first gas purge gap 17 having an annular shape is formed at this portion when the semiconductor wafer W is clamped. Here, an overlapping amount L1 (a passage length of the first gas purge gap 17) of the peripheral portion of the semiconductor wafer W and the inner periphery of the clamp ring 11 during clamping is several millimeters (mm).

A peripheral portion of the clamp ring member 11 is arranged above the bent portion 14 formed at the upper end of the partition wall 13, and a second gas purge gap 18 having an annular shape is formed therebetween. The width (height) of the second gas purge gap 18 is about 500 μm, which is about ten times larger than the width of the first gas purge gap 17. An overlapping amount of the peripheral portion of the clamp ring member 11 and the bent portion 14 (a passage length of the second gas purge gap 18) is, e.g., about 10 mm. Accordingly, inert gases in the inert gas purge area 15 can be discharged through both gaps 17 and 18 into a processing space.

An inert gas supply mechanism 19 for supplying an inert gas to the inert gas purge area 15 is provided at the bottom portion of the processing chamber 1. The inert gas supply mechanism 19 includes: a gas nozzle 20 for introducing an inert gas, e.g., Ar gas, into the inert gas purge area 15; an Ar gas supply source 21 for supplying an Ar gas as the inert gas; and a gas line 22 for supplying an Ar gas from the Ar gas supply source 21 to the gas nozzle 20. Further, the gas line 22 is provided with a mass flow controller (MFC) 23 serving as a flow rate controller, and opening/closing valves 24 and 25. Instead of Ar gas, other rare gas such as He gas or the like may be used as the inert gas.

A transmission window 30 made of a heat ray transmission material such as quartz or the like is air-tightly provided at a place right under the mounting table 3 at the bottom portion of the processing chamber 1, under which a box-shaped heating chamber 31 is arranged to surround the transmission window 30. The heating chamber 31 has therein a plurality of heating lamps 32 serving as a heating unit, which are installed on a rotatable table 33 serving as a reflective mirror as well. The rotatable table 33 is rotated by a rotating motor 34 provided at a bottom portion of the heating chamber 31 through a rotation axis. Accordingly, heat rays emitted from the heating lamps 32 are irradiated to the backside of the mounting table 3 through the transmission window 30, thereby heating the mounting table 3.

Furthermore, a gas exhaust port 36 is provided at a peripheral portion of the bottom portion of the processing chamber 1. The gas exhaust port 36 is connected to a gas exhaust line 37 connected to a vacuum pump (not shown). By exhausting gases through the gas exhaust port 36 and the gas exhaust line 37, a pressure in the processing chamber 1 can be maintained at a certain vacuum level. Formed at a sidewall of the processing chamber 1 are a loading/unloading port 39 for loading and unloading a semiconductor wafer W and a gate valve 38 for opening and closing the loading/unloading port 39.

Meanwhile, a shower head 40 for supplying a source gas or the like into the processing chamber 1 is provided at a ceiling portion of the processing chamber 1 to face the mounting table 3. The shower head 40 includes a disc-shaped head main body 41 which is made of, e.g., aluminum, and has a space 41a therein. A gas inlet port 42 is provided at a ceiling portion of the head main body 41. The gas inlet port 42 is connected, through a line 51, to a processing gas supply mechanism 50 for supplying processing gases required to form an Sr—Ti—O-based film. A plurality of gas injection holes 43 for discharging the gas supplied into the head main body 41 to the processing space provided in the processing chamber 1 is formed over the entire surface of the bottom portion of the head main body 41, so that the gas is discharged onto the entire surface of the semiconductor wafer W.

Further, a diffusion plate 44 having a plurality of gas distribution holes 45 is disposed in the space 41a of the head main body 41, so that the gas can be more uniformly supplied to the surface of the semiconductor wafer W. Moreover, cartridge heaters 46 and 47 for temperature control are built in the sidewall of the processing chamber 1, the sidewall of the shower head 40 and the wafer facing surface of the shower head 40 where the gas injection holes are provided, so that the sidewall of the processing chamber 1 and portions of the shower head which contact with the gas can be maintained at a predetermined temperature.

The processing gas supply mechanism 50 includes an Sr source material reservoir 52 for storing an Sr source material, a Ti source material reservoir 53 for storing a Ti source material, an oxidizer supply source 54 for supplying an oxidizer, and a dilute gas supply source 55 for supplying a dilute gas, e.g., Ar gas, for diluting the gas in the processing chamber 1.

The line 51 connected to the shower head 40 is connected to a line 56 extending from the Sr source material reservoir 52, a line 57 extending from the Ti source material reservoir 53 and a line 58 extending from the oxidizer supply source 54. The line 51 is also connected to the dilute gas supply source 55. The line 51 is provided with a mass flow controller (MFC) 60 serving as a flow rate controller, and valves 61 and 62 disposed at an upstream and a downstream side thereof. Further, the line 58 is provided with a mass flow controller (MFC) 63 serving as a flow rate controller and valves 64 and 65 located at an upstream and a downstream side thereof.

The Sr source material reservoir 52 is connected via the line 67 to a carrier gas supply source 66 for supplying a carrier gas for bubbling, e.g., Ar gas or the like. The line 67 is provided with a mass flow controller (MFC) 68 serving as a flow rate controller, and valves 69 and 70 located at an upstream and a downstream side thereof. Moreover, the Ti source material reservoir 53 is connected via the line 72 to a carrier gas supply source 71 for supplying a carrier gas such as Ar gas or the like. The line 72 is provided with a mass flow controller (MFC) 73 serving as a flow rate controller, and valves 74 and 75 located at an upstream and a downstream side thereof.

The Sr source material reservoir 52 and the Ti source material reservoir 53 are provided with heaters 76 and 77, respectively. Besides, the Sr source material stored in the Sr source material reservoir 52 and the Ti source material stored in the Ti source material reservoir 53 are supplied to the processing chamber 1 through bubbling while being heated by the heaters 76 and 77. Although it is not shown, a line for supplying the Sr source material or the Ti source material in a vaporized state is also provided with a heater.

Formed at an upper sidewall of the processing chamber 1 is a cleaning gas inlet port 81 for introducing NF₃ gas as a cleaning gas. The cleaning gas inlet port 81 is connected to a line 82 for supplying NF₃ gas. The line 82 is provided with a remote plasma generator 83. Thus, NF₃ gas supplied through the line 82 is turned into a plasma in the remote plasma generator 83 and supplied into the process chamber 1, thereby cleanning the processing chamber 1. Moreover, the remote plasma generator 83 may be provided at a place located right above the shower head 40 so that a cleaning gas can be supplied through the shower head 40. Besides, F₂ may be used instead of NF₃, and plasma-less thermal clean using ClF₃ or the like may be performed without using a remote plasma.

The film forming apparatus 100 includes a process controller 90 including a micro processor (computer), and components of the film forming apparatus 100 are connected to and controlled by the process controller 90. Further, the process controller 90 is connected to a user interface including a keyboard through which an operator inputs commands for controlling respective components of the film forming apparatus 100 and/or a display for visually displaying operation statuses of respective components of the film forming apparatus 100.

Moreover, the process controller 90 is connected to a storage unit 92 for storing therein control programs to be used in realizing various processes performed by the film forming apparatus 100 under the control of the process controller 90, programs, i.e., recipes to be used in performing predetermined processes by the respective components of the film forming apparatus 100 under processing conditions, various databases and/or the like. The recipes are stored in a storage medium of the storage unit 92. The storage medium may be a fixed device such as a hard disk or the like, or a portable device such as a CD-ROM, a DVD, a flash memory or the like. Besides, the recipes may be properly transmitted from other devices via, e.g., a dedicated line.

If necessary, any one of the recipes is read out from the storage unit 92 in accordance with an instruction inputted from the user interface 91 and executed by the process controller 90. Accordingly, a desired process is performed in the film forming apparatus 100 under the control of the process controller 90.

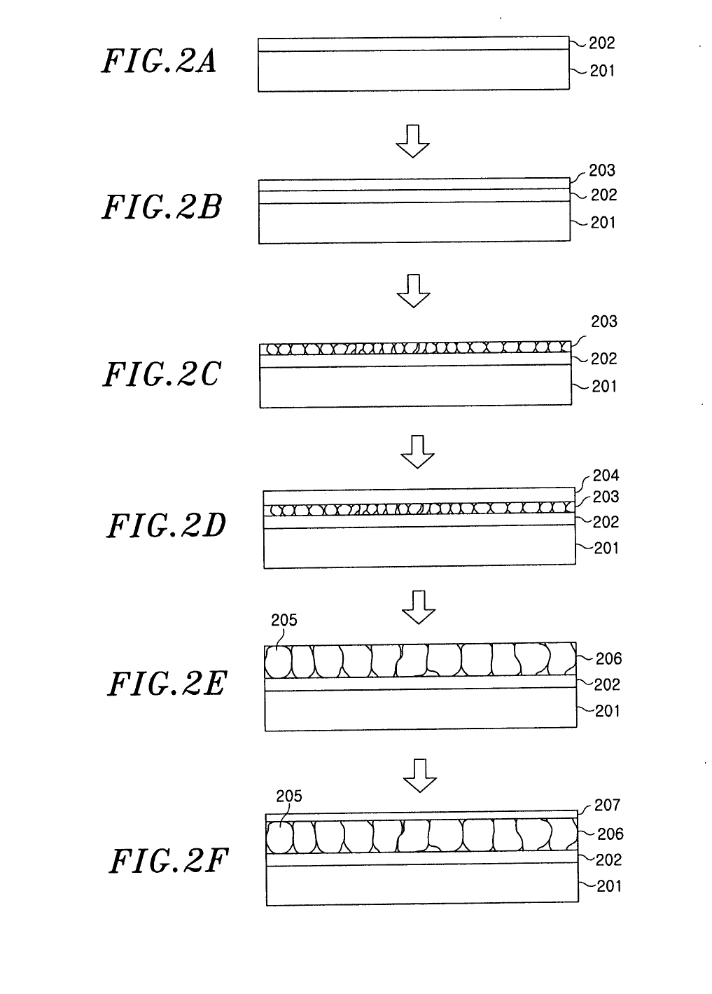

Hereinafter, embodiments of a film forming method performed by the film forming apparatus configured as described above will be explained with reference to process cross sectional views shown in FIGS. 2A to 2F.

Here, a semiconductor wafer W having a structure shown in FIG. 2A in which an Ru film 202 serving as a lower electrode is formed on an Si substrate 201 through a TiN film or the like (not shown) as needed is used, and an Sr—Ti—O film is formed on the Ru film 202.

As illustrated in FIG. 2B, a first Sr—Ti—O film 203 having a thin thickness ranging from about 2 to 10 nm is formed by sequentially introducing an Sr source material, a Ti source material and an oxidizer into the processing chamber 1 while performing a purge step using a dilute gas therebetweeen (a first process).

Next, as shown in FIG. 2C, the first Sr—Ti—O film 203 is annealed for crystallization at a temperature preferably ranging from 500 to 750° C., e.g., about 600° C., by an annealing furnace in a non-oxidizing atmosphere such as an N₂ atmosphere (a second process).

Then, as depicted in FIG. 2D, a second Sr—Ti—O film 204 having a thickness ranging from about 5 to 20 nm is formed on the first Sr—Ti—O film 203 by sequentially introducing an Sr source material, a Ti source material and an oxidizer into the processing chamber 1 while carrying out a purge step therebetween (a third process).

Thereafter, the second Sr—Ti—O-based film 204 is annealed for crystallization at a temperature preferably ranging from about 500 to 750° C., e.g., about 600° C., by the annealing furnace in a non-oxidizing atmosphere such as an N₂ atmosphere (a fourth process).

The annealing step of the fourth process may be performed by using a rapid thermal annealing (RTA) method or a conventional heating furnace. In case of using the heating furnace, a heating temperature is maintained preferably for about 5 to 200 minutes. In case of using the RTA method, a heating temperature is maintained preferably for about 10 to 600 seconds.

Actually, when the annealing step was performed under an N₂ atmosphere at about 600° C. for about 10 minutes and about 120 minutes in the heating furnace, an SiO₂ equivalent oxide thickness (EOT) was about 0.55 and 0.52 nm, respectively. On the other hand, when the annealing step was performed under an N₂ atmosphere at about 500° C. for about one minute through the RTA method, an EOT was about 0.54 nm. The annealing step of the second process is performed preferably under the same conditions as those described above.

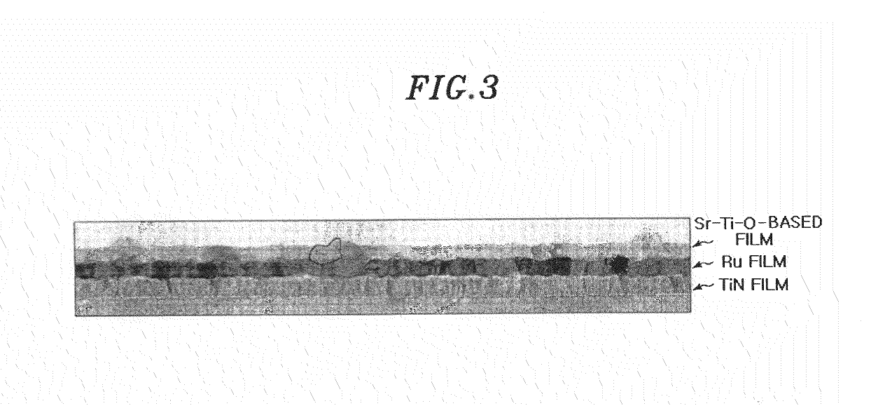

The second Sr—Ti—O film 204 is formed on the crystallized first Sr—Ti—O film 203 and thus can be easily crystallized. After the annealing step of the fourth process is completed, crystals of the first Sr—Ti—O-based film and the second Sr—Ti—O-based film are connected to each other in a film thickness direction, thereby forming a single (integrated) layer 206 having stable large SrTiO₃ single crystal grains 205 crystallized in the film thickness direction as shown in FIG. 2E. Moreover, the formation of the large crystal grains 205 leads to a high dielectric constant. FIG. 3 shows an actual scanning electron microscopic (SEM) image of the single layer 206.

As described above, the second Sr—Ti—O film 204 can be easily crystallized. Especially, when the second Sr—Ti—O film 204 is formed at a temperature of about 300° C. or higher, e.g., about 345° C., which is higher than a conventional film formation temperature of about 290° C., it can be crystallized without annealing in the as-deposited state. Actually, a (110) peak strength (cps) of an SrTiO₃ crystal which was measured by an XRD (X-ray diffractometer) after the formation and annealing of the first Sr—Ti—O film 203 was about 32.5. On the other hand, a peak strength measured immediately after the formation of the second Sr—Ti—O film 204 at about 345° C. was about 39. In other words, it was found that the second Sr—Ti—O film 204 formed at a higher temperature was crystallized even in as-deposited state. However, the annealing step of the fourth process is necessary in order to ensure crystallization.

Upon completing the annealing step of the fourth process, a curing step as a heat treatment may be performed under an oxidizing atmosphere, if necessary (fifth process). The curing step has a function of recovering oxygen vacancy of the crystallized second Sr—Ti—O film 204 and improving electrical characteristics (SiO₂ equivalent oxide thickness (EOT) and leakage current). The curing step is performed preferably at a temperature ranging from about 350 to 500° C., and more preferably from about 400 to 450° C., e.g., about 420° C., which is lower than that of the annealing step of the fourth process, and maintained preferably for three minutes or more.

Although a temperature and an O₂ concentration higher than a certain level are required to improve the electrical characteristics, a high temperature and a high O₂ concentration inflict damages on, e.g., the Ru film serving as the lower electrode of the Sr—Ti—O film and the like. Therefore, when the O₂ concentration is greater than or equal to about 20%, it is preferable to set the curing temperature to be lower than or equal to about 420° C. When the curing temperature is about 425° C., it is preferable to set the O₂ concentration to be lower than or equal to about 5%.

The improvement of the electrical characteristics by the curing step is described as follows: when a single-layer Sr—Ti—O film having an Sr/Ti atomic ratio of about 1.26 and a thickness of about 5 nm was annealed in a furnace under an N₂ atmosphere at about 600° C. for about two hours and then cured at about 420° C. for about 10 minutes with an O₂ concentration of about 20%, an SiO₂ equivalent oxide thickness (EOT) was reduced from about 0.74 nm to about 0.53 nm, and a leakage current decreased from about 5×10⁻⁴ A/cm² (at 1 V) to 5×10⁻⁵ A/cm² (at 1 V).

After the first Sr—Ti—O film having a thickness of about 5 nm was formed and annealed in the furnace under an N₂ atmosphere at about 600° C. for about two hours, the second Sr—Ti—O film having a thickness of about 5 nm was formed and annealed under an N₂ atmosphere at about 600° C. for about two hours. Thereafter, the curing step was performed at about 420° C. for about ten minutes with an O₂ concentration of about 20%. As a result, an SiO₂ equivalent oxide thickness (EOT) of about 0.50 nm and a leakage current of about 2.3×10⁻⁵ A/cm² (at 1V) were obtained.

In the Sr—Ti—O film formed as the above, grain boundaries are formed in the film thickness direction as the single crystal grains is crystallized in the film thickness direction. This may cause a leakage current. In order to minimize the leakage current, a third Sr—Ti—O film 207 substantially not crystallized is formed on the single layer 206, as depicted in FIG. 2F (sixth process). The formation of the Sr—Ti—O film substantially not crystallized makes it possible to block the grain boundaries in the single layer 206 and minimize the leakage current. The third Sr—Ti—O film 207 may be slightly crystallized as long as the grain boundaries can be blocked. If the thickness of the third Sr—Ti—O film 207 is too large, a dielectric constant thereof decreases. Therefore, the film thickness of the third Sr—Ti—O film 207 is preferably a thickness ranging from about 1 to 5 nm.

In the sixth process, an oxide film substantially not crystallized may be formed instead of the third Sr—Ti—O film 207. The oxide film may be a TiO₂ film, an Al₂O₃ film, or an La₂O₃ film. In that case, a film thickness is preferably within a range from about 0.3 to 2 nm.

Hereinafter, specific conditions of film formation performed by the film forming apparatus 100 will be provided.

At first, the gate valve 38 opens, and a semiconductor wafer W is loaded into the processing chamber 1 through the loading/unloading port 39 and mounted on the mounting table 3. The semiconductor wafer W is heated by the mounting able 3 that has been heated by heat rays emitted from the heating lamps 32 and transmitted through the transmission window 30.

Then, while a dilute gas, e.g., Ar gas, is supplied at a flow rate ranging from about 100 to 800 mL/sec (sccm) from a dilute gas supply source 55, the processing chamber 1 is vacuum-exhausted by a vacuum pump (not shown) through the gas exhaust port 36 and gas exhaust line 37 so that a pressure in the processing chamber 1 is controlled at a level ranging from about 39 to 665 Pa. At this point, the semiconductor wafer W is heated to a temperature within a range, e.g., from 200 to 400° C.

Next, a flow rate of a dilute gas, e.g., Ar gas, is set to be maintained within a range from about 100 to 500 mL/min (sccm), and a pressure in the processing chamber 1 is controlled to be kept within a range from about 6 to 266 Pa. The pressure in the processing chamber 1 is controlled by an automatic pressure controller (APC) provided in the gas exhaust line 37.

In that state, actual film formation is started.

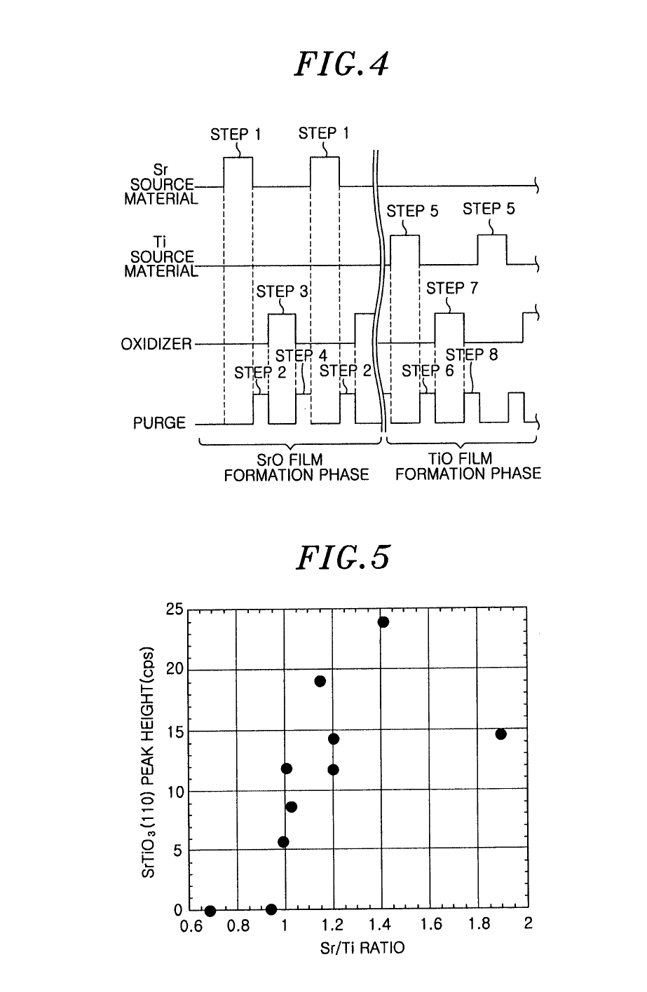

As can be seen from FIG. 4, the actual film formation is carried out by repeating an SrO film formation phase for forming a thin SrO film and a TiO film formation phase for forming a thin TiO film plural times. The SrO film formation phase includes: supplying an Sr source material into the processing chamber 1 (step 1); purging the processing chamber 1 (step 2); decomposing and oxidizing the Sr source material by supplying an oxidizer into the processing chamber 1 (step 3); and purging the processing chamber 1 (step 4). The TiO film formation phase includes: supplying a Ti source material into the processing chamber 1 (step 5); purging the processing chamber 1 to remove an excessive Ti source material (step 6); decomposing and oxidizing the Ti source material by supplying the oxidizer into the processing chamber 1 (step 7); and purging the processing chamber 1 to remove an excessive oxidizer (step 8).

By alternately repeating the SrO film formation phase and the TiO film formation phase, the film formation can be carried out using a conventional ALD method. When it is required to control a Sr/Ti atomic ratio, a film forming process may include a sequence of repeating either one or both of the SrO film formation phase plural times continuously and the TiO film formation phase plural times continuously. Although the TiO film has a composition of TiOx (X being 1 to 2) due to actual variation in concentration of oxygen in the TiO film formation phase, it is indicated as a “TiO film” for convenience.

Since the first and the second Sr—Ti—O film need to be crystallized, the first and the third process are carried out under conditions which facilitate the crystallization. However, the fifth process for forming the third Sr—Ti—O film is performed under conditions which do not substantially cause to crystallize.

Whether the Sr—Ti—O film is easy to crystallize varies by an Sr/Ti atomic ratio. When the Sr/Ti atomic ratio is smaller than 1, the Sr—Ti—O film is hardly crystallized even by annealing. This will be described with reference to FIG. 5. FIG. 5 shows relation between an Sr/Ti atomic ratio (X-axis) and a SrTiO₃ (110) peak height which is measured by an XRD after annealing (Y-axis). As illustrated in FIG. 5, when the Sr/Ti atomic ratio is smaller than 1, a crystal peak is not observed, which denotes that the Sr—Ti—O film is substantially not crystallized even through annealing.

Hence, it can be understood from FIG. 5 that the first and the second Sr—Ti—O film are formed preferably under the condition in which the film composition, i.e., the Sr/Ti atomic ratio, is greater than or equal to 1. However, the atomic ratio actually changes depending on conditions, and the Sr—Ti—O film may be crystallized when the Sr/Ti atomic ratio is about 0.9. Meanwhile, when the Sr/Ti atomic ratio is greater than about 1.4, the electrical characteristics deteriorate. For that reason, the first and the second Sr—Ti—O film are formed preferably under the condition in which an Sr/Ti atomic ratio in the film is within a range from about 0.9 to 1.4, and preferably from about 1.1 to 1.3.

On the contrary, the third Sr—Ti—O film is requested not to substantially crystallize, so that the film formation of the third Sr—Ti—O film is preformed preferably under the condition in which the Sr/Ti atomic ratio is smaller than 1.

The Sr/Ti atomic ratio can be controlled by controlling, e.g., the number of repeating the SrO film formation phase and the TiO film formation phase. When the Sr/Ti atomic ratio is smaller than 1, it may be zero. In that case, a TiO₂ (Titania) film is formed.

Hereinafter, the steps 1 to 8 of the film formation will be described.

In the step 1, an Sr source material is supplied by bubbling from the Sr source material reservoir 52 heated to about 150 to 230° C. by the heater 76 into the processing chamber 1 through the shower head 40. The Sr source material may be a conventionally used organic Sr compound. For example, it is preferable to use Sr(DPM)₂ (Bis(dipivaloylmethanato) strontium), Sr(C₅(CH₃)₅)₂ (Bis(pentamethylcyclopentadienyl)strontium) or the like. Especially, Sr(C₅(CH₃)₅)₂ that has a comparatively high vapor pressure and is easily handled can be preferably used among materials having a low vapor pressure.

When the Sr source material is supplied, a dilute gas, e.g., Ar gas, is supplied at a flow rate ranging from about 100 to 500 mL/min (sccm) from the dilute gas supply source 55, and a carrier gas, e.g., Ar gas, is supplied at a flow rate ranging from about 50 to 500 mL/min (sccm) from the carrier gas supply source 66. The supply of the Sr source material (step 1) is performed for, e.g., about 0.1 to 20 seconds.

In the step 3 for oxidizing the Sr source material, the oxidizer is supplied from the oxidizer supply source 54 into the processing chamber 1 via the showerhead 40. Accordingly, the Sr source material adsorbed onto the surface of the semiconductor wafer W is decomposed and oxidized, thereby forming an SrO film. The supply of the oxidizer (step 3) is performed for, e.g., about 0.1 to 20 seconds, while a dilute gas, e.g., Ar gas, is supplied at a flow rate of about 100 to 500 mL/min (sccm) from the dilute gas supply source 55.

As the oxidizer, O₃ gas, O₂ gas, H₂O, or a plasma of O₂ gas is preferably used. When O₃ gas is used as the oxidizer, it is supplied at a flow rate ranging from about 50 to 200 g/m³N from the oxidizer supply source 54 by using an ozonizer. At this time, O₂ gas may be supplied along with the O₃ gas at a flow rate ranging from about 100 to 1000 mL/min (sccm). When H₂O is used as the oxidizer, it is supplied preferably at a flow rate ranging from about 2 to 50 mL/min (sccm).

In the step 5, a Ti source material is supplied by bubbling from the Ti source material reservoir 53 into the processing chamber 1 through the shower head 40. As the Ti source material, it is preferable to use alkoxide such as Ti(OiPr)₄ (Titanium(IV) iso-propoxide), Ti(OiPr)₂(DPM)₂ (Di iso-propoxy Bis(dipivaloylmethanato) Titanium) or the like.

In that case, the Ti source material reservoir 53 containing Ti(OiPr)₄ is heated to a temperature within a range from about 40 to 70° C., and the Ti source material reservoir 53 containing Ti(OiPr)₂(DPM)₂ is heated to a temperature within a range from about 150 to 230° C.

When the Ti source material is supplied, a dilute gas, e.g., Ar gas, is supplied at a flow rate ranging from about 100 to 500 mL/min (sccm) from the dilute gas supply source 55, and a purge gas, e.g., Ar gas, is supplied at a flow rate ranging from about 100 to 500 mL/min (sccm) from the carrier gas supply source 71. The supply of the Ti source material (step 5) is carried out for, e.g., about 0.1 to 20 seconds.

In the step 7 for oxidizing the Ti source material, the oxidizer is supplied from the oxidizer supply source 54 into the processing chamber 1 via the showerhead 40 under the same conditions as those of the step 3 while the dilute gas is supplied from the dilute gas supply source 55. Accordingly, the Ti source material is decomposed and oxidized, thereby forming a TiO film.

During the purge step of the steps 2, 4, 6 and 8, the supply of the Sr source material gas, the Ti source material gas and the oxidizing gas is stopped, and a dilute gas, e.g., Ar gas, is supplied at a flow rate ranging from about 200 to 1000 mL/min (sccm) from the dilute gas supply source 55 into the processing chamber. Further, the purge step may be performed by fully opening a pressure control mechanism of the processing chamber 1 without supplying gas. This step is performed for, e.g., about 0.1 to 20 seconds.

An Sr—Ti—O-based film having a predetermined thickness can be formed by alternately repeating the SrO film formation phase of the steps 1 to 4 and the TiO film formation phase of the steps 5 to 8 or by repeating a predetermined number of times a cycle in which the SrO film formation phase is carried out a predetermined number of times and then the TiO film formation phase is carried out a predetermined number of times, depending on a desired Sr/Ti atomic ratio.

Upon completion of the film formation, a dilute gas is supplied at a predetermined flow rate from the dilute gas supply source 55 and, then, the supply of all gases is stopped. Next, the processing chamber is vacuum-exhausted and, then, the semiconductor wafer W is unloaded from the processing chamber 1 by a transfer arm.

The process controller 90 controls the valves or the mass flow controllers in accordance with the above-described sequence based on the recipes stored in the storage unit 92.

Hereinafter, test examples of actual film formation performed by the embodiment of the present invention will be described.

### TEST EXAMPLE 1

In the apparatus of FIG. 1, after a temperature of a mounting table was heated to about 300° C. by controlling a lamp power so that a 200-mm Si wafer can be heated to about 290° C. at a pressure for film forming, the Si wafer having a Ru film as a lower electrode was loaded into the processing chamber 1 by the arm of a transfer robot and an Sr—Ti—O-based film was formed. Herein, Sr(C₅(CH₃)₅)₂ contained in the Sr source material reservoir 52 heated to about 160° C. was supplied as an Sr source material into the processing chamber 1 through bubbling method while using Ar gas as a carrier gas.

Further, Ti(OiPr)₄ contained in a the Ti source material reservoir 53 heated to about 45° C. was supplied as a Ti source material into the processing chamber 1 through bubbling method while using Ar gas as a carrier gas. Furthermore, O₃ gas having concentration of about 180 g/m³N was used as an oxidizer. The O₃ gas was obtained by passing O₂ gas at a flow rate of about 500 mL/min (sccm) and N₂ gas at a flow rate of about 0.5 mL/min (sccm) through an ozonizer.

When the Si wafer was mounted on the mounting table by the arm, a pressure in the processing chamber was controlled to be maintained at about 133 Pa (1 Torr) for about 60 seconds while the dilute Ar gas was supplied at a flow rate of about 300 mL/min (sccm). During that, the temperature of the Si wafer was increased to a film formation temperature, i.e., about 290° C. Then, the pressure in the processing chamber was controlled to be maintained at about 40 Pa (0.3 Torr) for about 10 seconds while the dilute Ar gas was supplied at a flow rate of about 300 mL/min (sccm). By repeating the steps 1 to 8 under the following conditions, the first Sr—Ti—O film was formed.

Specifically, in the step 1, the Si source material supply process was executed for about 10 seconds by supplying carrier Ar gas at a flow rate of about 50 mL/min (sccm) and dilute Ar gas at a flow rate of about 200 mL/min (sccm) and exhausting the processing chamber 1 by fully opening the pressure control mechanism of the processing chamber 1. In the step 2, the purge process was carried out for about 10 seconds by fully opening the pressure control mechanism of the processing chamber 1 without supplying gas.

In the step 3, the Si source material oxidizing process was carried out for about two seconds while using O₃ gas as an oxidizer and exhausting the processing chamber 1 by fully opening the pressure control mechanism of the processing chamber 1. In the step 4, the purge process was performed for about 10 seconds by fully opening the pressure control mechanism of the processing chamber 1 without supplying gas.

In the step 5, the Ti source material supply process was performed for about 10 seconds by supplying carrier Ar gas at a flow rate of about 100 mL/min (sccm) and dilute Ar gas at a flow rate of about 200 mL/min (sccm) and exhausting the processing chamber 1 by fully opening the pressure control mechanism of the processing chamber 1. As in the step 2, the purge process of the step 6 was carried out for about 10 seconds by fully opening the pressure control mechanism of the processing chamber 1 without supplying gas.

In the step 7, the Ti source material oxidizing process was performed under the same conditions as those of the step 3 except that an oxidation time was about five seconds. The purge process of the step 8 was performed under the same conditions as those of the step 4.

Although the steps 1 to 8 are performed by fully opening the pressure control mechanism of the processing chamber 1, the pressure in the processing chamber 1 changes in accordance with existence/nonexistence of supplied gases and flow rates thereof. For example, the pressure in the processing chamber 1 was about 0.36 Torr in the step 1; about 0 Torr in the steps 2, 4, 6 and 8; about 0.52 Torr in the step 3; and about 0.39 Torr in the step 5.

A cycle of performing the SrO film formation phase of the steps 1 to 4 twice, the TiO film formation phase of the steps 5 to 8 twice, the steps 1 to 4 twice and then steps 5 to 8 once was repeated eleven times. Thereafter, the processing chamber 1 was exhausted by fully opening the pressure control mechanism of the processing chamber 1 while the dilute Ar gas was supplied at a flow rate of about 300 mL/min (sccm) for about 30 seconds. Then, the Si wafer was unloaded from the processing chamber 1.

In the unloaded Si wafer, it was found that an Sr—Ti—O-based film having a thickness of about 5 nm was formed on the Ru film serving as a lower electrode. Further, a film composition, i.e., an Sr/Ti atomic ratio, measured by an XRF (x-ray fluorescence spectrometer) was about 1.2.

Next, the Si wafer was loaded into an annealing furnace and annealed under an N₂ atmosphere at about 600° C. for about 120 minutes, so that the first Sr—Ti—O film was crystallized into SrTiO₃.

Thereafter, the Si wafer was loaded into the film forming apparatus of FIG. 1 again and mounted on the mounting table by the arm. Then, the dilute Ar gas was supplied at a flow rate of about 300 mL/min (sccm) and the pressure in the processing chamber was controlled to be maintained at about 133 Pa (1 Torr) for about 60 seconds. During that, the temperature of the Si wafer was increased to a film forming temperature, e.g., about 290° C. Next, the pressure in the processing chamber was controlled to be maintained at about 40 Pa (0.3 Torr) for about 10 seconds by supplying the dilute Ar gas at a flow rate of about 300 mL/min (sccm).

Next, a cycle of performing the SrO film formation phase of the steps 1 to 4 twice, the steps 5 to 8 twice, the steps 1 to 4 twice and then the steps 5 to 8 once was repeated fifteen times. The processing chamber 1 was exhausted by fully opening the pressure control mechanism of the processing chamber 1 while the dilute Ar gas was supplied at a flow rate of about 300 mL/min (sccm) for about seconds. Then, the Si wafer was unloaded from the processing chamber.

In the unloaded wafer, it was seen that the second Sr—Ti—O-based film was formed on the first Sr—Ti—O-based film, and a total thickness of the first and the second Sr—Ti—O-based film was about 12 nm. Moreover, a film composition, i.e., an Sr/Ti atomic ratio, measured by an XRF (X-ray fluorescence spectrometer) was about 1.2.

Further, the Si wafer was loaded into the annealing furnace and annealed under an N₂ atmosphere at about 600° C. for about 120 minutes, and the second Sr—Ti—O film was crystallized into SrTiO₃. As a result, it was found that crystals of the first Sr—Ti—O-based film and those of the second Sr—Ti—O-based film were connected in a film thickness direction and this lead to formation of a single layer having large SrTiO₃ single crystal grains crystallized in the film thickness direction (see FIG. 3).

Thereafter, the Si wafer was loaded into the film forming apparatus of FIG. 1 again and mounted on the mounting table by the arm. Next, the dilute Ar gas was supplied at a flow rate of about 300 mL/min (sccm), and the temperature of the Si wafer was increased to a film formation temperature, i.e., about 290° C., while a pressure in the processing chamber was controlled to be maintained at about 133 Pa (1 Torr) for about 60 seconds. Then, the pressure in the processing chamber was controlled to be maintained at about 40 Pa (0.3 Torr) for about 10 seconds while the dilute Ar gas was supplied at a flow rate of about 300 mL/min (sccm).

Next, there was performed a cycle of performing the SrO film formation phase of the steps 1 to 4 twice, the steps 5 to 8 twice, the steps 1 to 4 twice, the steps 5 to 8 twice, the steps 1 to 4 once and the steps 5 to 8 twice. After repeating this cycle four times, the processing chamber 1 was exhausted by fully opening the pressure control mechanism of the processing chamber while the dilute Ar gas was supplied at a flow rate of about 300 mL/min (sccm) for about 30 seconds. Then, the Si wafer was unloaded from the processing chamber. In this cycle, concentration of O₃ was about 100 g/m³N unlike that supplied for the formation of the first and the second Sr—Ti—O film.

As a result of monitoring the unloaded wafer, it was found that the third Sr—Ti—O-based film was formed on the single layer formed before, and a total film thickness including that of the third Sr—Ti—O-based film was about 14 nm. Further, a composition of the third Sr—Ti—O-based film, i.e., an Sr/Ti atomic ratio, measured by an XRF (x-ray florescence spectrometer) was about 0.7.

Thereafter, the Si wafer was loaded into the annealing furnace and annealed under an N₂ atmosphere at about 600° C. for about 120 minutes. The third Sr—Ti—O-based film was not crystallized even after the annealing process, so that the grain boundaries in the single layer formed by the first and the second Sr—Ti—O-based film were blocked.

As for the Sr—Ti—O-based film thus formed, an SiO₂ equivalent oxide thickness (EOT) was about 1.2 nm, a leakage current (Jg) was about 2×10⁻⁶ A/cm² (at 1 V), and a relative dielectric constant was about 44.

### TEST EXAMPLE 2

Here, an Sr—Ti—O-based film was formed by the film forming apparatus of FIG. 1 under the same conditions as those of the test example 1 in temperatures, film forming source materials and an oxidizer. First, the first Sr—Ti—O film was formed and annealed under the same conditions as those of the test example 1 except that the O₃ concentration was about 100 g/m³N and a cycle of sequentially performing the SrO film formation phase three times, the TiO film formation phase twice, the SrO film formation phase twice, the TiO film formation phase twice, the SrO film formation phase twice and the TiO film formation phase once was repeated seven times. As a result, the first Sr—Ti—O film having a thickness of about 5 nm was formed.

Next, the second Sr—Ti—O film was formed under the same conditions as those of the test example 1 except that the O₃ concentration was about 100 g/m³N and the same sequence as that of the first Sr—Ti—O film formation was executed. A thickness of the second Sr—Ti—O film was about 10 nm, and a total thickness was about 15 nm. Next, annealing was performed under the same conditions as those of the test example 1. As a result, crystals of the first Sr—Ti—O-based film and those of the second Sr—Ti—O-based film were connected in a film thickness direction and this lead to formation of a single layer having large SrTiO₃ single crystal grains crystallized in the film thickness direction.

For the Sr—Ti—O-based film thus formed, there were measured an SiO₂ equivalent oxide thickness (EOT) of about 1.7 nm and a leakage current (Jg) of about 2.5×10⁻⁴ A/cm² (at 1 V).

### TEST EXAMPLE 3

Here, an Sr—Ti—O-based film was formed and annealed under the same conditions as those of the test example 2 except that a second Sr—Ti—O film was formed by using as an oxidizer O₃ having a concentration of about 180 g/m³N and by repeating 22 times a cycle of sequentially performing the SrO film formation phase twice, the TiO film formation phase twice, the SrO film formation phase twice, and the TiO film formation phase once. As a result, the Sr—Ti—O-based film having a thickness and a crystallized state same as those in the test example 2 was obtained.

The Sr—Ti—O-based film thus formed had an SiO₂ equivalent oxide thickness (EOT) of about 1.5 nm and a leakage current (Jg) of about 3.0×10⁻⁶ A/cm² (at 1V) which were reduced compared to those in the test example 2.

### TEST EXAMPLE 4

After an Sr—Ti—O-based film was formed and annealed under the same conditions as those of the test example 3, a TiO₂ film having a thickness of about 1 nm which is not crystallized was formed thereon under the following film forming conditions.

Specifically, the TiO film formation phase was repeated 20 times by the film forming apparatus of FIG. 1 under the same conditions as those of the test example 3 in temperatures, film forming source materials, an oxidizer and its concentration.

The Sr—Ti—O-based film thus formed had an SiO₂ equivalent oxide thickness (EOT) of about 1.5 nm and a leakage current (Jg) of about 8.0×10⁻⁷ A/cm² (at 1 V) which were decreased compared to those in the test example 3.

### TEST EXAMPLE 5

Here, an Sr—Ti—O-based film was formed by the film forming apparatus of FIG. 1 under the same conditions as those of the test example 1 in temperatures, film forming source materials and an oxidizer. First, a first Sr—Ti—O film was formed and annealed under the same conditions as those of the test example 1 except that an O₃ concentration was about 180 g/m³N; a cycle of sequentially performing the SrO film formation phase twice, the TiO film formation phase twice, the SrO film formation phase twice, the TiO film formation phase twice, the SrO film formation phase twice, the TiO film formation phase twice, the SrO film formation phase twice and the TiO film formation phase once was repeated seven times; and an annealing time was about 10 minutes. Accordingly, the first Sr—Ti—O film having a thickness of about 5 nm was formed and annealed.

Next, a second Sr—Ti—O film was formed under the same conditions as those of the first Sr—Ti—O film. A thickness of the second Sr—Ti—O film was about 5 nm, and a total thickness of the first and the second Sr—Ti—O film was about 10 nm. Then, the second Sr—Ti—O film was annealed under the same conditions as those of the first Sr—Ti—O film.

As a result, an SiO₂ equivalent oxide thickness (EOT) of about 0.49 nm and a leakage current (Jg) of about 1.7×10⁻⁴ A/ cm² (at 1V) were obtained. Further, the annealed second Sr—Ti—O film was cured (thermally processed) under an oxidizing atmosphere at about 420° C. for about 10 minutes with an O₂ concentration of about 20%. In consequence, an SiO₂ equivalent oxide thickness (EOT) of about 0.50 nm and a leakage current (Jg) of about 2.3×10⁻⁵ A/cm² (at 1V) were obtained.

### TEST EXAMPLE 6

Here, the formation and annealing of the first Sr—Ti—O film, the formation and annealing of the second Sr—Ti—O film and the curing process were carried out under the same conditions as those of the test example 5. Then, an Al₂O₃ film having a thickness of about 1 nm was formed as a third layer by an ALD method using TMA (trimethylaluminum) and O₃ as source materials. A total thickness of the laminated films was about 11 nm. The third layer had an SiO₂ equivalent oxide thickness (EOT) of about 0.52 and a leakage current (Jg) of about 1.7×10 ⁶ A/cm² (at 1 V).

### TEST EXAMPLE 7

Here, the formation and annealing of the first Sr—Ti—O film, the formation and annealing of the second Sr—Ti—O film and the curing process were performed under the same conditions as those of the test example 5. Then, a TiO film having a thickness of about 1 nm was formed as a third layer by repeating 18 times the TiO film formation phase of the steps 5 to 8. A total thickness of the laminated films was about 11 nm. The third layer had an SiO₂ equivalent oxide thickness (EOT) of about 0.51 nm and a leakage current (Jg) of about 2×10⁻⁶ A/cm² (at 1 V).

The present invention can be variously modified without being limited to the above-described embodiments.

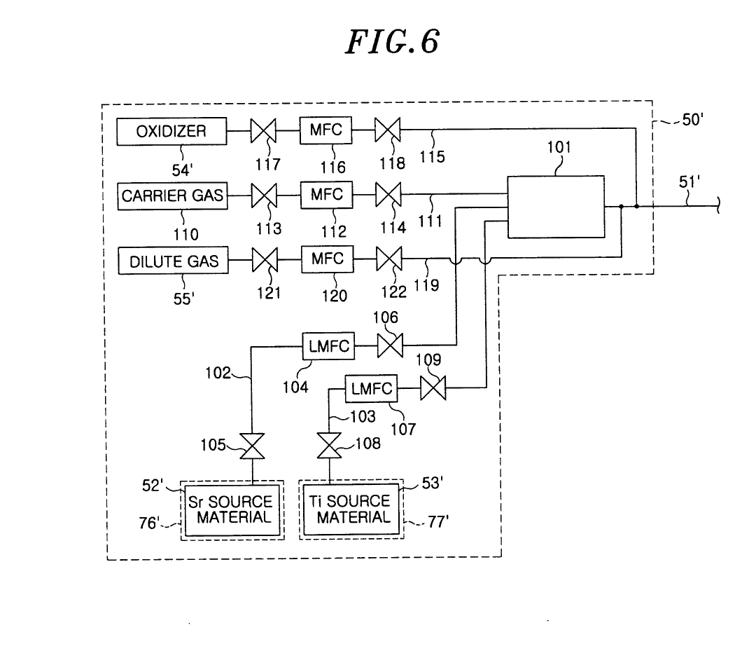

For example, instead of the processing gas supply mechanism 50 for supplying a source material by bubbling which is used in the above-described film forming apparatus, it is also possible to use a processing gas supply mechanism 50′ for supplying a source material by using a vaporizer as shown in FIG. 6. The processing gas supply mechanism 50′ includes an Sr source material reservoir 52′ for storing an Sr source material dissolved in a solvent; a Ti source material reservoir 53′ for storing a Ti source material dissolved in a solvent; an oxidizer supply source 54′ for supplying an oxidizer; and a vaporizer 101 for vaporizing the Sr source material and the Ti source material.

A line 102 is provided from the Sr source material reservoir 52′ to the vaporizer 101, and a line 103 is provided from the Ti source material reservoir 53′ to the vaporizer 101. A liquid is supplied from the Sr source material reservoir 52′ and the Ti source material reservoir 53′ to the vaporizer 101 by a pressure-feed gas, a pump or the like. The line 102 is provided with a liquid mass flow controller (LMFC) 104 serving as a flow rate controller, and valves 105 and 106 located at an upstream and a downstream side thereof. Further, the line 103 is provided with a liquid mass flow controller (LMFC) 107 and valves 108 and 109 located at an upstream and a downstream side thereof.

The Sr source material reservoir 52′ and the Ti source material reservoir 53′ are provided with a heater 76′ and a heater 77′, respectively. Further, the Sr source material dissolved in the solvent and stored in the Sr source material reservoir 52′ and the Ti source material dissolved in the solvent and stored in the Ti source material reservoir 53′ are heated to predetermined temperatures by the heaters 76′ and 77′ and supplied in a liquid state to the vaporizer 101 by a pump, a pressure-feed gas or the like. Moreover, although it is not illustrated, lines for allowing passage of the Sr source material and the Ti source material may be provided with heaters.

A line 51′ is provided from the vaporizer 101 to the showerhead 40. The vaporizer 101 is also connected to a line 111 which extends from the carrier gas supply source 110 for supplying a carrier gas, e.g., Ar gas. The carrier gas is supplied to the vaporizer 101, so that an Sr source material and a Ti source material that have been heated to the temperatures within a range, e.g., from about 100 to 200° C. and then vaporized in the vaporizer 101 are supplied into the processing chamber 1 through the line 51′ and the shower head 40.

The line 111 is provided with a mass flow controller (MFC) 112 serving as a flow rate controller and valves 113 and 114 located at an upstream and a downstream side thereof. A line 115 is provided from an oxidizer supply source 54′ to the line 51′ and an oxidizer is supplied into the processing chamber 1 through the line 115, the line 51′ and the shower head 40. The line 115 is provided with a mass flow controller MFC 116 serving as a flow rate controller and valves 117 and 118 located at an upstream and a downstream side thereof.

The gas supply mechanism 50′ includes a dilute gas supply source 55′ which supplies a dilute gas such as Ar gas or the like to dilute gases in the processing chamber 1. A line 119 is provided from the dilute gas supply source 55′ to the line 51′, so that Ar gas for dilution can be supplied into the processing chamber 1 through the line 119, the line 51′ and the showerhead 40. The line 119 is also provided with a mass flow controller (MFC) 120 serving as a flow rate controller and valves 121 and 122 located at an upstream and a downstream side thereof.

When an Sr—Ti—O film is formed by using the gas supply mechanism 50′, a film formation process is performed in accordance with basically the same sequence as that described above, except that it differs in the Sr source material supply process of the step 1 and the Ti source material supply process of the step 5.

In the Sr source material supply process of step 1, the Sr source material in the Sr source material reservoir 52′ is dissolved in a solvent such as octane, cyclohexane, toluene or the like. At this time, the concentration thereof is preferably within a range from about 0.05 to 1 mol/L. The Sr source material is supplied to the vaporizer 101 heated to a temperature within a range from about 100 to 300° C. and then vaporized therein. Further, the dilute gas, e.g., Ar gas, is supplied at a flow rate ranging from about 100 to 500 mL/min (sccm) from the dilute gas supply source 55′, and the carrier gas, e.g., Ar gas, is supplied at a flow rate ranging from about 100 to 500 mL/min (sccm) from the carrier gas supply source 110. This process is performed for a substantially same time period as that of the bubbling supply.

In the Ti source material supply process of the step 3, the Ti source material is dissolved in a solvent such as octane, cyclohexane, toluene or the like in the Ti source material reservoir 53′, supplied to the vaporizer 101 heated to a temperature within a range from about 100 to 200° C., and vaporized therein. The concentration thereof is preferably within a range from about 0.05 to 1 mol/L. At this time, a dilute gas, e.g., Ar gas, is supplied at a flow rate ranging from about 100 to 500 mL/min (sccm) from the dilute gas supply source 55′, and a carrier gas, e.g., Ar gas, is supplied at a flow rate ranging from about 100 to 500 mL/min (sccm) from the carrier gas supply source 110. Alternatively, a Ti source material in a liquid state may be supplied to the vaporizer 101 and vaporized therein. Further, this process is performed for a substantially same time period as that of the bubbling supply.

In the film forming apparatus of the above embodiment, a substrate to be processed is heated by lamps. However, it may be heated by a resistance heater. Further, although a semiconductor wafer is used as a substrate to be processed in the above-described embodiments, the substrate to be processed is not limited thereto and may be another substrate such as a glass substrate for use in an FPD or the like.

Moreover, in the aforementioned embodiments, the processing chamber is exhausted by fully opening the pressure control mechanism during film formation. However, a pressure in the processing chamber may be maintained at a desired level ranging from about 13 to 266 Pa by operating the pressure control mechanism. In addition, although a purge process is performed by fully opening the pressure control mechanism without supplying gases in the aforementioned embodiments, a purge process may be performed by exhausting the processing chamber by fully opening the pressure control mechanism or by maintaining the pressure in the processing chamber at a pressure ranging from about 20 to 266 Pa, while supplying an inert gas, e.g., Ar gas, at a flow rate ranging from about 100 to 1000 mL/min (sccm).

### INDUSTRIAL APPLICABILITY

An Sr—Ti—O-based film formed by the method in accordance with the present invention is effectively used in an electrode for MIM-structured capacitors.

What is claimed is:

1. An Sr—Ti—O-based film forming method comprising:
loading a substrate having an Ru film formed thereon into a processing chamber;
forming a first Sr—Ti—O-based film having a thickness smaller than or equal to about 10 nm on the Ru film by introducing a gaseous Ti source material, a gaseous Sr source material and a gaseous oxidizer into the processing chamber;
annealing the first Sr—Ti—O-based film to crystallize;
forming a second Sr—Ti—O-based film on the first Sr—Ti—O-based film by introducing the gaseous Ti source material, the gaseous Sr source material and the gaseous oxidizer into the processing chamber; and
annealing the second Sr—Ti—O-based film to crystallize.

2. The Sr—Ti—O-based film forming method of claim 1, further comprising, after annealing the second Sr—Ti—O-based film, forming a third Sr—Ti—O-based film which is substantially uncrystallized.

3. The Sr—Ti—O-based film forming method of claim 2, wherein the third Sr—Ti—O-based film is formed under a condition in which an Sr/Ti atomic ratio is smaller than 1.

4. The Sr—Ti—O-based film forming method of claim 1, further comprising, after annealing the second Sr—Ti—O-based film, forming an oxide film which is substantially uncrystallized.

5. The Sr—Ti—O-based film forming method of claim 4, wherein the oxide film is one of a TiO₂ film, an Al₂O₃ film and an L₂O₃ film.

6. The Sr—Ti—O-based film forming method of claim 1, wherein the annealing of the first Sr—Ti—O-based film and the annealing of the second Sr—Ti—O-based film are performed under a non-oxidizing atmosphere at the temperature range from 500 to 750° C.

7. The Sr—Ti—O-based film forming method of claim 1, further comprising, after annealing the second Sr—Ti—O-based film to crystallize, curing to introduce oxygen into the film under an oxidizing atmosphere.

8. The Sr—Ti—O-based film forming method of claim 7, wherein the curing is performed at the temperature range from 350 to 500° C.

9. The Sr—Ti—O-based film forming method of claim 1, wherein the forming of the first and/or the second Sr—Ti—O-based film is executed by performing each of an SrO film formation phase and an TiO film formation phase multiple times, wherein the SrO film formation phase includes: introducing the gaseous Sr source material into the processing chamber and adsorbing the Sr source material onto the substrate; oxidizing the Sr source material by introducing the gaseous oxidizer into the processing chamber; and purging the processing chamber, and the TiO film formation phase includes: introducing the gaseous Ti source material into the processing chamber and adsorbing the Ti source material onto the substrate; oxidizing the Ti source material by introducing the gaseous oxidizer into the processing chamber; and purging the processing chamber.

10. The Sr—Ti—O-based film forming method of claim 9, comprising repeating a sequence, wherein the sequence includes performing the SrO film formation phase multiple times successively and/or performing the TiO film formation phase multiple times successively.

11. The Sr—Ti—O-based film forming method of claim 1, wherein the Sr source material is a cyclopentadienyl compound.

12. The Sr—Ti—O-based film forming method of claim 1, wherein the Ti source material is alkoxide.

13. The Sr—Ti—O-based film forming method of claim 1, wherein the oxidizer is O₃ or O₂.

14. The Sr—Ti—O-based film forming method of claim 1, wherein the formation of the first Sr—Ti—O-based film and the formation of the second Sr—Ti—O-based film are carried out under a condition in which an Sr/Ti atomic ratio in the film ranges from about 0.9 to 1.4.

15. A storage medium for storing a program which runs on a computer and, when executed, controls a film forming apparatus to perform a Sr—Ti—O-based film forming method including:
loading a substrate having an Ru film formed thereon into a processing chamber;
forming a first Sr—Ti—O-based film having a thickness smaller than or equal to about 10 nm on the Ru film by introducing a gaseous Ti source material, a gaseous Sr source material and a gaseous oxidizer into the processing chamber;
annealing the first Sr—Ti—O-based film to crystallize;
forming a second Sr—Ti—O-based film on the first Sr—Ti—O-based film by introducing the gaseous Ti source material, the gaseous Sr source material and the gaseous oxidizer into the processing chamber; and
annealing the second Sr—Ti—O-based film to crystallize.
